(19) United States
(12) Patent Application Publication
(10) Pub. No.: US 2009/0186306 A1
(43) Pub. Date: Jul. 23, 2009

(54) Polymeric microfluidic devices from liquid thermoset precursors

(76) Inventor: Klas Tommy Haraldsson, Jarfalla (SE)

Correspondence Address: LYNN E BARBER, P O BOX 16528, FORT WORTH, TX, 76162, US

(21) Appl. No.: 12/291,275

(22) Filed: Nov. 7, 2008

Related U.S. Application Data
(60) Provisional application No. 61/002,467, filed on Nov. 9, 2007.

(51) Int. Cl. G03F 7/20; G03B 27/54

(52) U.S. Cl. 430/322; 355/67

(57) ABSTRACT

A method and apparatus for the fabrication of polymeric microfluidic devices through sequential photolithographic polymerization of micropatterned polymeric layers.

### CROSS REFERENCE TO RELATED APPLICATIONS

This application claims priority from U.S. provisional application Ser. No. 61/002,467 filed Nov. 9, 2007, which is incorporated herein by reference.

### BACKGROUND OF THE INVENTION

1. Field of the Invention

The present invention relates generally to the fabrication of microfluidic devices and in particular, the fabrication of microfluidic devices via a photolithographic technique that utilizes highly collimated UV or visible light in combination with a binary photomask defined projected image to create micropatterned devices from liquid polymer precursors.

2. Description of the Prior Art

Microfluidic devices are finely detailed constructs designed to deliver precise amounts of fluid to predetermined on-device locations. Typically, microfluidic devices contain minute channels with precise geometries, microreservoirs for chemical reactions and detection windows to allow for external probing of the nature and extent of biochemical and chemical reactions conducted in the device.

Microfluidic devices are considered ideal for performing various biotechnical tasks such as biochemical analysis, disease detection and chemical compound analysis, both qualitative and quantitative.

State of the art microfabrication methods enable production of very intricate microfluidic devices. The most advanced devices are called micro total analysis systems (microTAS) in which electronics, mechatronics and channels on minute scales, even including nanosized components, are combined. Typically these devices are fabricated via standardized semiconductor fabrication methods using silicon wafer substrates. However, silicon micromachining is costly, which has led to an increased focus on polymeric microfluidic devices. These are not yet as advanced as the silicon based devices, but nano-sized patterns and trenches are routinely fabricated on surfaces using nano imprint lithography. Also, highly intricate 3D polymeric microfluidic devices with high spatial resolution are fabricated via advanced photolithographic schemes such as two-photon laser polymerization.

Thus, the problems facing the microfluidics industry are not due to a lack of precision or ability to fabricate very advanced single devices. Instead, the problems lie in the expense and time consumption for design and fabrication of these devices, where each may take years to perfect. Furthermore, these devices are not multifunctional platforms as their microelectronic counterparts, e.g. semiconductor processors, but solve a single specific task. It is almost impossible to economically fabricate specific devices in this manner since each device targets a small niche application.

Also, certain necessary device properties are difficult to routinely fabricate even in singular devices using state of the art methods: 1) connections between the everyday world to chip microfluidic channels and minute reaction chambers via macro to micro interfaces on the device; 2) durable surface chemistries/properties, i.e. surface chemistries that remain unchanged for at least one year and; 3) robust enclosure of trenches in order to form microfluidic channels.

In an attempt to avoid the cost of silicon and glass micromachining and the low speed of two photon lithography, the microfluidics community has turned to polymer rapid prototyping methods and polymer mass fabrication methods to solve microfluidic device fabrication problems. The community has had most success with standard thermoplastic fabrication methods with minor changes incorporated to adapt the methods to microfluidic applications. For example, injection molding is used successfully to fabricate simple polymeric microfluidic devices for the diagnostics community, e.g. devices for quantitative determination of blood gases and electrolytes; and hot embossing is used to fabricate trenches on a base plate which, combined with other parts, forms a device for the cost effective determination of cholesterol. Still, advanced microfluidic applications such as quantitative determination of blood analytes present in low concentration are still not economically or technically feasible.

In the prior art, several techniques have been described as capable of polymeric microfluidic device fabrication, including thermoplastic materials microfabrication techniques and thermoset materials microfabrication techniques:

Microinjection molding produces micropatterns by shaping a heated thermoplastic material in a mold cavity. To date, microinjection molding is only suitable for relatively simple devices in high volume production and is unsuitable for even moderately complex devices due to difficulties in producing undercuts and robust channel enclosure via lid attachment. Further, materials are limited, and surface modification techniques are generally not reliable for the projected shelf life of microfluidic devices (2 years). Developments that aim for rational production of microfluidic devices via injection molding are still pursued, but many problems remain unsolved: insufficient materials selection, difficulties in fabricating covered channels and insufficient surface treatment lifetime and quality.

Hot embossing is a similar process to microinjection molding, i.e. a plastic deformation of thermoplastic polymers. Hot embossing is more suitable than microinjection molding for more complex devices in medium volume production. The main problems are fabrication of through-holes since any attempt at producing a through-hole invariably results in a thin blocking polymer layer. No effective after-treatment process to alleviate the situation has been described. Materials selection is more limited than in microinjection molding, surface modifications have the same durability and quality issues, and facile connections between the everyday world to on chip microfluidic channels are prevented by the inability to form through-holes.

Laser ablation is a well known art for producing micropatterns in various materials directly from CAD drawings. It is unsuitable for mass fabrication of microfluidic devices due to limited production speed.

To alleviate the problems with thermoplastic polymers, many microfabrication techniques that utilize thermoset formulations have been designed. A few of these are potentially suitable for microfluidic mass fabrication. Stereolithographic methods are used to fabricate micropatterned prototypes by sequentially joining photolithographically patterned thin layers. In a slightly different method, WO2005110721 shows the use of a projection system and definition of the interface by using a transparent plane. The main problems for the fabrication of microfluidic devices with these methods are very limited fabrication speeds due to an excessive number of layers needed for device fabrication and/or poor resolution which prevents accurate fabrication of microfluidic features.

The failure of stereolithography to rapidly and accurately produce microdevices has spurred development of alternative technologies aiming for industrially relevant production rates. Microfluidic tectonics, U.S. Pat. No. 6,821,898, has been designed to rapidly produce simple microfluidic devices with enclosed channels. The main problem with this method is inflexibility in material choices for the top and bottom portions of the channel, poor resolution since the curing takes place through a very thick plastic lid, difficulties in surface treatments after the device has been fabricated and unsuitability for massively parallel fabrication due to the use of small prefabricated cassettes.

A similar approach for the fabrication of single layer polymeric micropatterned devices is described by Hudson et al., Langmuir 20, 10020 (2004), and Cabral et al., J. Micromech. Micromach. 14, 153 (2004). In these devices, the plastic lid has been replaced with a glass plate and the cassette walls with solid but changeable spacers. Further, collimated light is used to limit feature broadening. The main problems with the process described in the articles are the use of collimated light with inadequate collimation (i.e. 2.6 degree half angle beam divergence) and a direct placement of a photomask on top of the glass plate. The first problem limits the resolution in the polymer to 50-75 micron, according to experimental results, which is an order of magnitude above what is acceptable for microfluidic applications. The latter problem is problematic for alignment of subsequent layers and limits the illuminated area to the size of the mask since no provision for moving the mask with adequate positional accuracy can be applied. Further, dust particles or other contaminants on the mask or the glass plate risks introducing air wedges between the glass plate and the mask which in turn may result in Newtonian rings and other optical phenomena that limit patterning accuracy.

The DesCAF process, U.S. Pat. No. 5,135,379; U.S. Pat. No. 5,171,490; and U.S. Pat. No. 6,547,552, is a variation on the stereolithographic theme since it uses a projection method, has an essentially parallel top that controls the thickness of the layers formed and works in a sequential fashion with the possibility of varying the thickness of the individual layers. The main features of this method are a film that is sandwiched between the parallel top and the liquid monomer where the film has a special coating that prevents complete curing in the interface. This allows for facile removal of the parallel top and monolithic finished devices due to covalent bonding of layers. The main weakness in this technology is the use of low intensity visible light with nonparallel light beams. This prevents construction of devices via polymerization of thick layers due to light divergence. Thus, many layers are needed for the fabrication of full devices which limits the fabrication speed of microfluidic devices to unacceptably low levels.

In the CLiPP technology, WO2004009489, microfluidic devices are fabricated in a sequential layer by layer fashion, similar to stereolithography. This technology utilizes collimated UV-light and a photomask to derive a pattern, has an essentially parallel top that controls the thickness of the layers formed and works in a sequential fashion with the possibility to vary the layer thickness from a few microns up to 1 mm. The main weakness in the process is the contact between the liquid and the photomask. This presents many problems with mask detachment, mask wear and mask expense when the fabrication area is increased.

Further, U.S. Pat. No. 6,875,553 describes how a thick layer of liquid photoresist is applied over a substrate and a photomask is pressed on top of distributed spacers that afford thickness control. While the technology is mainly intended for inkjet nozzle fabrication, it is suggested that fabrication of microfluidic devices is possible in this manner. The main weakness in this technology is the use of spacers, which are difficult to place with sufficient accuracy to ensure non-tapering layers. Furthermore, layer thicknesses other than available spacer thicknesses cannot be produced, which severely limits production of multilayer microfluidic devices. Also, liquid photoresist tends to wick between these spacers and the substrate or surface, resulting in larger than intended resist thickness.

The technologies presented above are almost exclusively incompatible which prevents simple process combinations to achieve mass fabrication of microfluidic devices. While many of these processes may be suitable for the particular purpose which they address, they are not as suitable for cost beneficial fabrication of polymeric microfluidic devices with good fluidic control, suppressed analyte adsorption, facile access points and adequate handling properties.

In these respects, the fabrication process that enables the fabrication of microfluidic devices with on-board connections between the everyday world to microfluidic channels and minute reaction chambers, durable surface properties that prevent analyte adsorption and robust enclosure of channels according to the present invention substantially departs from the conventional concepts and designs of the prior art, and in so doing provides microfluidic devices with hitherto unrealized usability and economies of scale.

A primary object of the present invention is to provide a method for the fabrication of a micropatterned polymeric layer with a predefined geometry and predefined materials properties from photosensitive materials through the use of a projected image created by highly collimated UV or visible light passing through a photomask onto a transparent restricting plane underneath which a photosensitive liquid material is immersed between said plane and a substrate.

Another object of the present invention is to provide a method for the fabrication of a micropatterned polymeric layer with sufficient geometrical precision to be suitable for microfluidic device applications by projecting an image with adequate precision using highly collimated UV or visible light so that each layer is constructed with the maximum thickness with respect to geometrical features and desired materials properties

Another object is to provide a batch method for prototype- and mass fabrication of polymeric microfluidic devices. This is accomplished by providing a fabrication area that is simultaneously, or in a sequential fashion, i.e. step and repeat, illuminated by a projected image that contains the pattern for several microfluidic devices. Furthermore, fabrication of devices from thick layers, 20-2000 micron, allows for a minimum amount of exposure steps to fabricate the desired device geometry.

Another object is to enable facile detachment of a polymerized layer from the top transparent plane. Facile separation is ensured through the use of a non-stick coating, e.g. lecithin, fluorinated compounds, silicones etc, or an active chemistry that prevents the polymerization of the uppermost surface via inhibition or significant reaction retardation.

Another object is to provide an apparatus for photolithographic fabrication of several polymer layers from liquid polymer precursors in a fabrication enclosure. The fabrication enclosure contains the liquid polymer precursor during the polymerization process and allows for a projected image to impinge on top of the fabrication enclosure. The enclosure comprises a top transparent enclosing element and a second enclosing element essentially parallel and opposite one another. The apparatus allows adjustment and measurement of the separation between the first and second enclosing element, thereby allowing control of the thickness of the first liquid layer that is to be polymerized within the fabrication enclosure. To ensure polymer layers of desired thickness despite polymerization shrinkage in previously polymerized layers, accurate detection of a zero thickness layer is provided. With the absolute position of the zero thickness layer determined, thickness settings for the subsequent layer are readily set by monitoring and adjusting the distance between the top of the previously polymerized layer and the transparent plate. In this manner, errors in set thickness and polymerization shrinkage are not propagated.

Alignment is performed via an in process overlay accuracy measurement of a previously polymerized structure and the mask used to define the projected image. The ability to align the first and second enclosing elements relative to one another allows alignment of the photomask with a pattern produced in a previous polymerization step.

Another object is to ensure formation of monolithic devices via covalent attachment of a subsequent layer to unreacted chemical functional groups and/or reinitiable species on the surface of a previously polymerized layer. These functional groups or reinitiable species are selected such that functional groups in the liquid polymer precursor in the subsequent layer react during the normal polymerization reaction that is utilized to solidify the layer. Monolithic devices may contain several different materials in terms of mechanical and chemical properties, e.g. soft and hydrophobic materials, glassy and hydrophilic materials and electrically conducting, e.g. electrical wiring from liquid polymer precursors or electrically insulating materials in desired portions of the device.

Other objects and advantages of the present invention will become obvious to the reader and it is intended that these objects and advantages are within the scope of the present invention.

### SUMMARY OF THE INVENTION

The general purpose of the present invention, which will be described subsequently in greater detail, is to provide new microfluidic devices made possible by the invention that enables many advantages with respect to device materials and geometries such as facile access points and device handling either alone or in any combination thereof.

A primary object of the present invention is to provide a method for the fabrication of a micropatterned polymeric layer with a predefined geometry and predefined materials properties from photosensitive materials through the use of a projected image created by highly collimated UV or visible light passing through a photomask onto a transparent restricting plane underneath which a photosensitive liquid material is immersed between said plane and a substrate. In this manner, a method for inexpensive and rapid mass fabrication of multiple micropatterned layers on a large fabrication area is achieved through the use of a small and inexpensive mask and a projected image that can be moved or magnified to cover fully a fabrication area with multiple individual micropatterned layers. Furthermore, keeping the mask from contact with abrasive or adhesive elements ensures long mask lifetimes, and thus superior fabrication economy. The highly collimated light allows for the fabrication of thick layers which ensures a minimum number of repeating steps, and thus a high production rate. The ability to define micro and macro-patterns via the projected image allows for macroscale facile access points and microscale connected elements.

To attain this, the present invention generally comprises processes and technical solutions that allow for the fabrication of polymeric microfluidic devices through the sequential photopolymerization of micro/macro patterned layers of pre-set thicknesses to provide monolithic microfluidic devices with desired material and geometrical properties. The process utilizes a photomask that is placed between a UV or visible light source and a fabrication area where the liquid polymer precursor is located. The photomask is used to block portions of incident UV or visible light emitted by a UV or visible light source which either emits highly collimated UV or visible light, e.g. a laser, or emits non-collimated UV or visible light that is subsequently highly collimated via optical assemblies. The image thus created by the highly collimated light, i.e. a collection of essentially parallel light beams, passing through the photomask, is projected onto a liquid photoreactive polymer precursor. The bottom portion of the liquid photoreactive polymer precursor is in contact with a substrate, which can be a thermoplastic polymer sheet, a glass plate, a silicon wafer or a previously polymerized layer, and the top portion is in contact with a transparent plate that defines the top of the liquid photoreactive polymer precursor. To fabricate microfluidic devices, layers are sequentially polymerized in the manner above until the desired device is fabricated.

To ensure monolithic devices, a sufficient concentration of polymerizable functional groups or reinitiable species is present on the surface of a previously polymerized layer. These groups polymerize simultaneously with the next layer, thus forming strong interlayer covalent bonds.

To ensure robust enclosure of trenches in order to form channels, sacrificial layers, e.g. wax, may be employed to prevent unwanted polymerization in previously polymerized layers, or a prefabricated lid may be transferred from a transparent rigid plane in a batchwise manner and monolithically incorporated in the device through photoinduced or thermally induced reactions.

In addition to these important features of the invention that will be described hereinafter, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

### BRIEF DESCRIPTION OF THE DRAWINGS

FIG. 1 schematically illustrates the fabrication machine set up. A reaction chamber is formed by a base (5), a substrate (4) and a transparent plate (3). In FIG. 1, a layer of a liquid (7) comprising a photopolymerizable precursor is formed between substrate (4) and transparent plate (3). The thickness of the liquid layer is adjusted prior to exposure to the projected image which is created by the light source (1) and the photomask (2) in the path of the light placed at a finite distance (6) to the transparent plate (3).

FIG. 2 illustrates the inhibition processes for facile separation of the transparent plate and the polymer layer. The underside of the transparent plate, i.e. the side that faces the liquid polymer precursor (7), is chemically modified, preferably having its surface treated with a release coating that prevents adhesion between the transparent plate (3) and the cured polymer layer (8). Active molecules inhibit, mediate chain transfer or retard the polymerization and result in a thin surface layer of uncured or partially cured polymer (9).

FIG. 3 schematically illustrates the concept of Largest Possible Structure, LPS. A simple device with an undercut (10) is shown and the LPS's (10a-c). This device is constructed from the lower LPS (10a), the middle LPS (10b) and top LPS (10c).

FIG. 4 schematically illustrates the use of transfer of solid elements from the transparent plate. The bottom layer of the device (11) is polymerized onto the substrate (4), and the top layer (12) is polymerized onto a transparent plate (3). Upon light mediated image projection, the second layer (7) is formed, covalently attached to the adjacent layers through the presence of unreacted polymerizable moieties on the surfaces of the previously polymerized layers.

FIG. 5 illustrates the use of a thin film to enclose a microfluidic device. The microfluidic device (14) comprising channels (16) and cavities (15) for reaction and detection covered with a thin film (13) is shown.

FIG. 6a-d shows schematically a machine embodiment of how magnification optics may be positioned in the light path before and/or after the photomask to allow for sufficiently large illumination area. In FIG. 6a-c optics that ensure highly collimated light with correct geometry and dimension (18) from the lightsource (17) is used above the photomask (2) illuminating the whole photomask. The illumination assembly (2, 17,18) can be moved relative to the fabrication area. The actual moving part(s) may be for example the fabrication area or the illumination part(s). FIG. 6a shows an example when the illumination assembly is at the center of the fabrication area, FIG. 6b shows the illumination assembly moved to the right side and FIG. 6c to the left side of the fabrication area. FIG. 6d. shows an example when the photomask (2) is illuminated to the whole transparent plate (3) by using magnification optics that ensure highly collimated light with correct patterning, geometry and dimensions (19).

FIG. 7a) shows schematically the fabrication area and polymerization chamber. A scale (22) is read by an optical or magnetic reader (21). A substrate (4) is placed on a movable bottom plate (5) of the apparatus and a transparent plate (3) is placed on top. The substrate is raised using micrometer screws (20) until the top of the substrate contacts with the transparent plate, which is the zero thickness layer where the contact is detected using a sensor (19). The configuration at the zero layer distance is shown in FIG. 7b).

### DETAILED DESCRIPTION OF THE INVENTION AND PREFERRED EMBODIMENTS THEREOF

The invention herein is a method that includes fabricating polymeric layers, sequentially adding these layers to fabricate polymeric microfluidic devices and providing a suitable fabrication machine for the fabrication of polymeric microfluidic devices. Included within the invention is a polymeric microfluidic device where a portion of the device is fabricated from photosensitive liquid polymer precursors where the primary object of the device is to contain, store and/or direct gases and liquids and at least one dimension of one device feature is less than 1000 microns.

The polymeric layers of the invention typically have a thickness between about 5 and about 2000 microns, preferably between about 20 and about 1000 microns. The individual polymeric layers that constitute the microfluidic device are typically patterned both in the macroscale, e.g. the outer boundaries of the device and macroscopic sample ports, and the microscale, e.g. channels and trenches inside a layer, so that the thickness of the film is not uniform across the area of the film.

In particular, the invention herein is a method for producing a plurality of geometrically structured polymeric layers comprising: a) placing a substrate on top of a base, the substrate having a liquid polymer precursor contained between the top of the substrate and the underside of an essentially transparent plate that is placed parallel to the substrate; b) placing a photomask above and parallel to the transparent plate; c) placing a light source above the photomask so that highly collimated light impinges at an angle normal to the photomask plane, and upon irradiation, a photomask determined pattern is projected onto the liquid polymer precursor and patterned polymer structures are formed.

The invention herein provides a method for making a polymeric layer on a substrate comprising the steps of: a) forming a layer of a liquid polymer precursor between the substrate and a transparent plate; b) exposing the liquid layer to a light mediated projected image through the transparent plate, thereby polymerizing one or more regions of the liquid polymer precursor to form a polymeric layer; and c) removing any unpolymerized region or regions of the liquid layer.

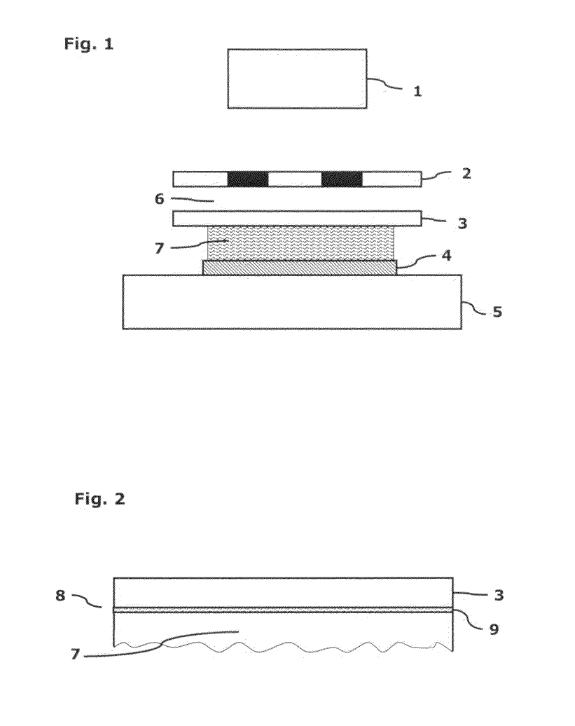

The formation of a layer and exposure of the layer to light are schematically illustrated in FIG. 1. The distance between the mask and the transparent plate is sufficiently large to ensure that no adverse effects of having two partially reflective surfaces parallel and in proximity are present. Potential problems thus avoided include standing waves, speckle, Newtonian rings etc., which may all lead to loss of patterning fidelity. The distance between the mask and the transparent plate is sufficiently small to ensure that small positional changes of the light source and/or the optics do not lead to loss of divergence or a creation of non-normal to the transparent plate light components. In FIG. 1, a reaction chamber is formed by a moveable base (5), a substrate (4) and a transparent plate (3). In FIG. 1, a layer of a liquid (7) comprising a photopolymerizable precursor is formed between substrate (4) and transparent plate (3). The thickness of the liquid layer is adjusted prior to exposure to the projected image which is created by the light source (1) and the photomask in the path of the light (2).

Liquid polymer precursors include any substance that contains an unsaturated moiety or other functionality that can be used in chain or step polymerization, or another moiety that may be polymerized in other ways. Such precursors include monomers and oligomers. Liquid polymer precursors suitable for use with the present invention are photopolymerizable. As used herein a photopolymerizable precursor is one that is capable of being polymerized by photoradiation, either ultraviolet (UV) or visible light. Some examples of precursors which are useful in the present invention include acrylates, methacrylates, epoxies, lactones, styrenes, maleimides, vinyl ether/maleate mixtures, vinyl ether/fumarate mixtures, vinyl ether maleimides and thiol-ene mixtures in conjunction with dissolved photoinitiator(s). Polymer precursors can contain reactive chemical groups that lack significant reactivity in the polymerization process in addition to containing polymerizable moieties. These reactive groups are subsequently used for bonding or surface modifications. An example of such a monomer is maleic acid, where the double bond readily polymerizes and the acid groups are used later for esterification in the presence of alcohols.

In a preferred embodiment, cationic type monomers/oligomers are mixed with radical type monomers/oligomers in the liquid polymer precursor for so called hybrid systems (Lin et al., Polymer 44 (17): 4781-4789, 2003). Monomers that contain cationic type and radical type functional groups in the same molecule are especially useful in this invention. An example of such a monomer is Bis[1-(methacryloylmethyl)-2-(vinyloxy)ethyl]terephthalate, which contains an epoxy and an acrylate reactive group. Another example is 3,4-Epoxy-Cyclohexylmethyl-Acrylate, CYCLMER A400, Daicel Chemical Industries, Ltd, Tokyo, Japan.

Preferred photocleavable photoinitiators form two active radical fragments. Preferred photocleavable initiators include phosphine oxides and phenones and quinones in combination with a hydrogen donor. Cationic initiators are also useful in the invention. A preferred embodiment is the use of combinations of photoinitiator types, i.e. a cationic photoinitiator and a radical type photoinitiator for so called hybrid systems. Preferred cationic initiators include aryldiazonium, diaryliodonium, and triarylsulfonium salts. Preferred initiators include, but are not limited to, Rose Bengal (Aldrich), Darocur 2959 (2-hydroxy-1-[4-(hydroxyethoxy)phenyl]-2-methyl-1-propanone, D2959, Ciba-Geigy), Irgacure 651 (2,2-dimethoxy-2-phenylacetophenone, 1651, DMPA, Ciba-Geigy), Irgacure 184 (1-hydroxycyclohexyl phenyl ketone, 1184, Ciba-Geigy), Irgacure 907 (2-methyl-1-[4-(methylthio)phenyl]-2-(4-morpholinyl)-1-propanone, 1907, Ciba-Geigy), Camphorquinone (CQ, Aldrich), isopropyl thioxanthone (quantacure ITX, Great Lakes Fine Chemicals LTD., Cheshire, England), Kip 100 and 150 from Fratelli-Lamberti, Darocur 1173 2-Hydroxy-2-methyl-1-phenyl-propan-1-one (Ciba Specialty Chemicals), and phosphine oxides such as Irgacure Bis(2,4,6-trimethylbenzoyl)-phenylphosphineoxide 819 (Ciba). CQ is typically used in conjunction with an amine such as ethyl 4-N,N-dimethylaminobenzoate (4EDMAB, Aldrich) or triethanolamine (TEA, Aldrich) to initiate polymerization.

The substrate may be temporary, i.e. not part of the finished device, or permanent i.e. part of the finished device. An example of a suitable temporary substrate is glass since it is easily reused and can be surface treated with silanes etc. to exhibit good reversible adhesion to the first polymer layer to ensure that the polymer layers stick to the glass during the processing while simultaneously allowing for facile device removal once the device is finished.

Temporary substrates may be used to exclude certain volumes of liquid polymer precursors to fabricate permanent structures in the polymer layer, e.g. ridges, nanopatterns etc. may be present on the temporary substrate facing the liquid polymer precursor and the negative image of the structure transferred to the polymer layer upon polymerization. Suitable permanent materials are various thermoplastic polymers, silicon, silicon oxides, glass, some metals and combinations of the above, e.g. a metallized glass substrate, depending on the end use of the microfluidic device.

Permanent substrates may be functional, i.e. contain geometrical structures, electronic circuits, sensors, detection windows, light sources, semiconductor electronic circuits, filters etc. Permanent substrates are preferably surface treated with reactive compounds that enable covalent bonding to the polymer layer, e.g. a glass substrate reacted with silanes that contain a polymerizable functional group, or the permanent substrates may contain native reactive groups on the surface, e.g. hydroxyl groups that can react with epoxy groups in a hybrid system, or the substrate may exhibit materials properties that allow for diffusion of some of the liquid polymer precursor monomers to form an interpenetrating network upon polymerization.

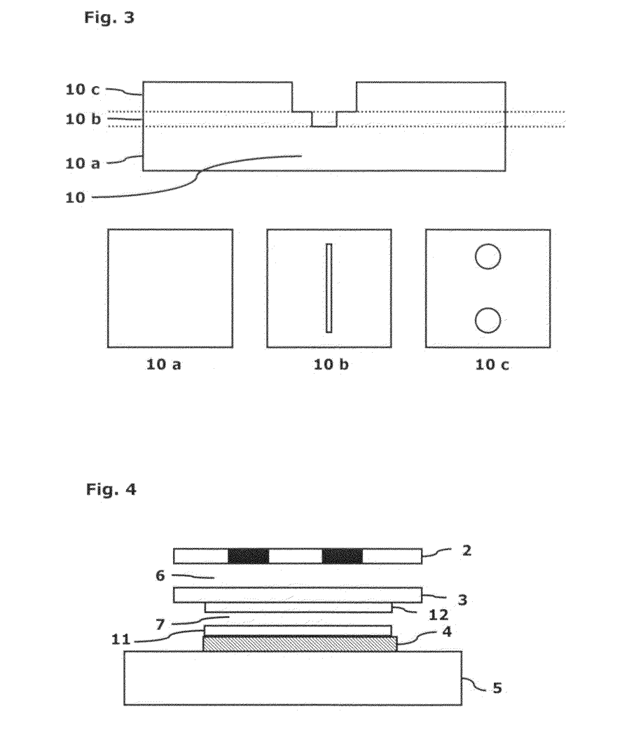

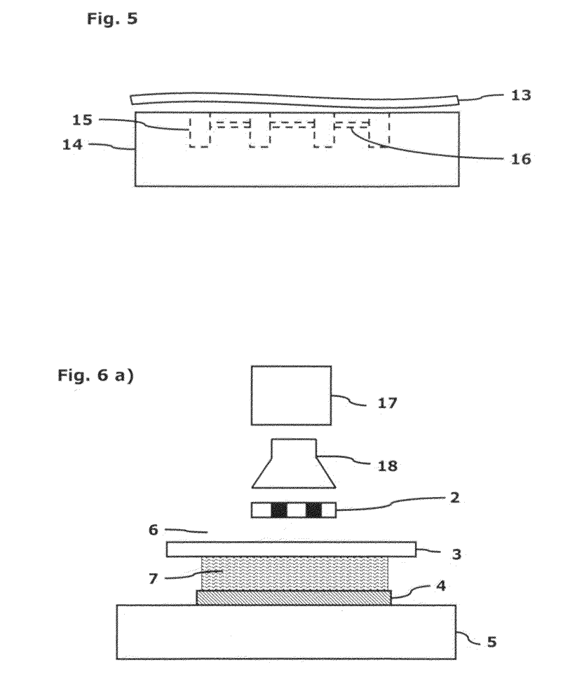

The invention provides a method for producing undercuts comprising a) providing a previously polymerized layer attached to the essentially transparent plate on the side facing the substrate; b) providing means to align said substrate to the previously polymerized layer; c) contacting the surfaces of the substrate and the previously polymerized layer; d) binding the surfaces covalently via light initiated chemical reactions; and e) detaching the essentially transparent plate from the attached previously polymerized layer. Thus, to fabricate microfluidic devices that contain undercuts, one or more of the trenches, depressions, or void volumes in the cured film can be filled with a sacrificial material to prepare a level surface. Subsequently, a new layer is formed on top of the layer that is filled with the sacrificial material via the previously described process of building a single layer. The microfluidic device is finished once the sacrificial layer is removed by heat and/or solvent to form unobstructed channels, depressions or void volumes. Alternatively, the device is built without the use of sacrificial layers until an undercut structure is needed, e.g. a top layer to transform trenches into channels. The undercut structure is transferred using a previously fabricated polymeric layer reversibly attached to the underside of the transparent plate in the fabrication chamber upon contact with the previously polymerized layer and exposure to light (flood light or a projected image), see FIG. 5. Generally, the fabrication area is readjusted for each subsequent layer. Typically, readjustment of the chamber involves adjusting the depth of the chamber by detecting the upper level of the previously polymerized layer and setting the zero layer thickness to the contact point between the previously polymerized layer and the transparent plate. Typically this readjustment of the depth of the chamber is accompanied with a change of the mask that is used to define the projected image. After fabrication is complete, the device(s) can be released from the substrate, or the substrate can form a part of the finished device. FIG. 3 shows what an assembly looks like after sequential polymerizations.

The contact between the transparent plate and the liquid polymer precursor is advantageous in many ways; a) no flow and leveling additives are necessary which greatly facilitates liquid polymer precursor recipe formulation and allows for relatively viscous liquid polymer precursors which greatly extends formulation freedoms; b) chemistries covalently bound to the underside of the transparent plate may be used to impede or inhibit the polymerization reaction to enable covalent bonding to subsequent layers and facile removal of the plate; c) atmospheric oxygen inhibition is greatly reduced which reduces the need for high initiation rates and/or the presence of chemicals used for chain consumption of oxygen which allows for diffusion of dissolved oxygen to help shape essentially vertical microfeatures, e.g. channel walls (Madou, Fundamentals of Microfabrication: The Science of Miniaturization, CRC Press, Boca Raton, 1997); d) the polymer layer takes on a negative image of the transparent plate, e.g. planar or a 3D shape, thus providing a convenient way to form the outer shape of the layer; and e) structures reversibly attached to the transparent plate may be transferred to the layer in the course of polymerization providing a convenient route to producing undercuts.

Having the transparent plate in contact with the liquid polymer precursor also allows for microfluidic device features that are difficult to produce with photolithography, such as nanometer sized structures, to be transferred to the polymer using a nanopatterned transparent plate. Having the transparent plate in contact with the liquid polymer precursor necessitates provisions for the facile removal of the transparent plate from the formed polymeric layer, see FIG. 2. In one embodiment, the underside of the transparent plate, i.e. the side that faces the liquid polymer precursor (7), is surface treated with a release coating that prevents adhesion between the transparent plate (3) and the cured polymer layer (8).

Thus, the essentially transparent plate has a surface on the side facing the photoreactive polymer precursor that is modified by chemicals, which preferably are essentially inert under normal photopolymerization conditions and form a release layer between the formed polymer and the essentially transparent plate. Alternatively, the chemicals are reactive chemicals that impart or transfer chemical reactivity to surfaces and liquids that are to be covalently bound in later process stages.

This release coating can be fluorinated organic molecules, silicones or lecithin etc. In another embodiment, the release coating is formed in situ by active molecules surface attached on the underside of the transparent plate. These active molecules inhibit, mediate chain transfer or retard the polymerization and result in a thin surface layer of uncured or partially cured polymer. The type of active molecule is determined by the photoactive initiator moiety and may be a tertiary amine or hydroxyl in the case of cationic polymerization and a hindered amine (TEMPO) or an iniferter molecule in the case of radical polymerization. The thickness of an inhibited layer is controlled by initiator concentration, initiator type, light intensity and light wavelength, where a high intensity light and high initiator concentration result in a thinner inhibited layer than a low light intensity combined with a low initiator concentration.

Having the transparent plate in contact with the liquid polymer precursor allows for the creation of surface active species in the polymer layer to impart/enhance covalent bonding between the polymer layer and a subsequently polymerized polymer layer. Surface active species can either be retained from partial reaction of the liquid polymer precursor or transferred from the underside of the transparent plate to the surface of the polymer layer.

Partial polymerization of the liquid polymer precursor is achieved in a variety of ways; a) inhibition or retardation of the reaction at the surface of the liquid polymer precursor layer; b) the inclusion of a monomer that contains active groups that are unreactive in a particular polymerization reaction but polymerizable in a subsequent polymerization reaction, e.g. epoxy first present in a radical polymerization is polymerizable in a second cationic polymerization step; and c) the use of monomers/oligomers that create extensive polymeric networks where the maximum conversion of active groups is limited by reaching the glass transition temperature, Tg, for the polymer layer before all active groups are reacted, e.g. certain methacrylate compounds, BisGMA, are known to give less than 40% conversion of the methacrylates before reaching Tg which leaves the unreacted methacrylates for a subsequent polymerization (Lovell et al. J Dent Res 78(8): 1469-1476, 1999). Many compositions suitable for radically polymerizable liquid polymer precursors have residual active groups in a concentration range of 10-30% residual groups. The amount of residual groups can be controlled by the functionality of the monomers/oligomers, i.e. the number of active groups present in each molecule, initiation rate and ambient temperature, where high functionality combined with a low initiation rate and low ambient temperature results in a higher concentration of residual active groups.

Suitable chemistries may be transferred from the transparent plate. For example, the plate may be coated with a thin layer of a compound that is capable of partially reacting with the liquid polymer precursor and partially remain unreacted to be available for subsequent reactions. Preferably, the compound has a high molecular weight, or is immiscible with the liquid polymer precursor to ensure that the penetration depth of the transferred molecules is limited to the top portion of the liquid polymer precursor.

The transferred compound may contain a radically reactive moiety and a cationically active moiety. The transferred compound may be an iniferter molecule (Doi et al. J Pol Sci A-Polymer Chemistry 32 (15): 2911-2918, 1994). An iniferter is a molecule which functions as an initiator, transfer agent, and terminator during free radical polymerization. Preferred iniferter precursors are those which dissociate at the appropriate wavelength of light. Preferred iniferter precursors include tetraethylthiuram disulfide (TED) and tetramethylthiuram disulfide (TMD). Iniferters suitable for used with the invention include, but are not limited to p-xylene bis(N,N-diethyldithiocarbamate) (XDT) and other compounds containing diethyl- or dimethyldithiocarbamate moieties.

The liquid layer is exposed to a light mediated image projected through the transparent plate onto the liquid layer. The preferred wavelengths of the light depend on the initiator used. Light used in the invention includes any wavelength capable of initiating polymerization. Preferred wavelengths of light include ultraviolet or visible. Any suitable light source may be used, including laser sources, LED sources and arc sources. The source may be broadband and/or narrowband. The light is preferably highly collimated when it impinges on the transparent plate. In this invention, “highly collimated” means less than 1 degree half angle divergence if the intensity distribution of the individual light beam divergences is similar, i.e. the intensity of the beams that have a 1 degree half angle divergence is similar in intensity to the beams that have 0.5 degree half angle divergence. If the intensity of the light beams with a higher divergence than 1 degree is significantly less, then “highly collimated” means that the collective intensity of the beams exceeding 1 degree half angle divergence is substantially less than the intensity of the light with less than 1 degree half angle divergence.

In the preferred embodiment of the invention, the highly collimated light simultaneously covers at least a substantial portion of the photomask, and is not simply a beam of light that rapidly scans across the photomask.

Also, in the preferred embodiment of the invention, the light source emanates from a diode-pumped solid-state laser passing through magnification and wave shape correction optics as discussed in further detail below.

The invention provides a variety of methods for making polymeric microfluidic devices with undercuts and lids. The microfluidic devices of the invention comprise one or more patterned polymeric layers. As used herein, a polymeric microfluidic device has at least one feature which has at least one dimension less than about 1000 microns.

In one embodiment, a multilayered device can be constructed by building the device one layer at a time. In another embodiment, a multilayered device can be constructed by attaching a previously made feature to the contact side of the transparent plate, and transferring it to a layer being formed. Combinations of these methods may also be used to build devices.

Multilayer devices are preferably constructed from so called largest possible structures, LPS. The device geometry is divided into LPS's by slicing it in the x-y plane (see FIG. 3). The LPS is characterized by; a) size in the xyz direction; b) topography; c) surface roughness; d) chemical composition; e) mechanical properties; f) surface chemistry. In FIG. 3 a simple device is shown and the LPS's are the lower LPS (10a), the middle LPS (10b) and top LPS (10c).

The methods of the invention can be used to make microfluidic devices with undercuts through sequential polymerization of multiple layers, preferably LPS's, and where the substrate thus can comprise a previously polymerized layer or layers on top of the support. In an embodiment, subsequent layers can be formed on each other to build up the microfluidic device. In this process, cavities such as trenches, depressions or void volumes in a layer are generally filled with a sacrificial material before a subsequent layer is attached. The sacrificial layer ensures that no liquid polymer precursor can access portions of the device where a polymer would obstruct flow, etc. Any excess sacrificial material deposited onto surfaces where attachment of the subsequent layer can be solvent polished before fabrication of the subsequent layer. This step can be repeated many times throughout the fabrication of the microfluidic device.

Sacrificial materials useful for the present invention are those that form a solid barrier to liquids and can be preferentially removed by changing the ambient conditions (magnetic, temperature, solvent, chemical, pH etc. etc). Suitable sacrificial materials include those that become liquid upon heating, simplifying their removal. The temperature at which the sacrificial material becomes liquid should be low enough so that none of the polymeric materials are damaged by the sacrificial material removal process. Sacrificial materials useful for the present invention include waxes. Specifically, an embodiment of the invention provides a method for forming a three-dimensional polymeric device on a substrate comprising the steps of: a) forming a first layer composed of a liquid polymer precursor which has a set thickness defined by the distance between the substrate and a transparent plate; b) exposing the first liquid layer to a projected image through the transparent plate, thereby polymerizing the layer in the pattern defined by the projected image; c) removing the transparent plate; d) removing any unpolymerized region or regions of the first liquid layer; e) filling the void volumes with a sacrificial material; f) solvent polishing the sacrificial material to make the level of the sacrificial material flush with the top of the void volume; g) forming a second layer composed of a liquid polymer precursor which has a set thickness defined by the distance between the top of the previously polymerized layer, determined by detecting the contact between the top and the transparent plate to establish the absolute position of the zero thickness layer, and a transparent plate; h) exposing the second liquid layer to a projected image through the transparent plate, thereby polymerizing the layer in the pattern defined by the projected image; i) removing any unpolymerized region or regions of the second liquid layer; and j) removing the sacrificial layer.

In an embodiment, a microfluidic device with undercuts and lids can be constructed by transferring solid elements from the underside, i.e. the side that faces the inside of the polymerization area, of the transparent plate to the finished device. Solid elements which may be transferred in this manner are those that are transparent and can be non-permanently attached to the transparent plate, and then transferred to the device with an adhesive, e.g. the liquid polymer precursor. Solid elements which can be transferred include, but are not limited to, previously formed polymeric layers, thermoplastic structures, and glass structures with appropriate surface treatments to allow for covalent attachment to the polymer layer. Previously formed polymeric layers may be attached to the transparent plate by using the transparent plate as a substrate in separate and previous fabrication of a single polymeric layer. This method is schematically shown in FIG. 4. In this method the bottom layer of the device (11) is polymerized onto the substrate (4), and the top layer (12) is polymerized onto a transparent plate (3). A preferred setup consists of a bottom layer, unpolymerized precursor with a defined thickness and a third layer attached to the underside of the transparent plate. Upon light mediated image projection, the second layer (7) is formed, covalently attached to the adjacent layers through the presence of unreacted polymerizable moieties on the surfaces of the previously polymerized layers.

In another embodiment, the second layer is of zero layer thickness and upon irradiation or heating the substance in the zero layer thickness adhesively bonds the two polymer layers together. The substance may be a liquid polymer precursor or it may be without a liquid polymer precursor. To ensure good contact between the polymer layers in the latter, a slight overpressure is used to elastically deform one or both polymer layers to provide good contact between the two polymer layers.

In some embodiments, it may be desirable to fabricate devices with multiple access ports for facile introduction of bioactive compounds into cavities and subsequently enclose the device with a thin polymeric film, see FIG. 5. In FIG. 5 a microfluidic device (14) comprising channels (16) and cavities for reaction and detection (15) covered with a thin film (13) is shown. To ensure that the adhesive used in the film does not interfere with the preferred surface chemistry in channels and voids, a partial layer at least covering the channels is created via the processes described above. In one embodiment, the top layer is composed of two layers, where the upper portion has materials tailored for the provision of very strong/irreversible adhesion of the thin polymeric film.

The above process may also be a convenient route for the formation of observation/detection windows without imparting severe liquid polymer precursor property limitations of the top layer, e.g. materials properties that ensure correct surface chemistries in combination with transparency etc., through proper selection of the thin film to ensure transparency at desired wavelengths.

The invention also provides an apparatus for photolithographic fabrication of a photo-polymerized layer from a layer of a liquid comprising a photopolymerizable polymer precursor, the apparatus comprising: a) a source of light; b) optical assemblies; and c) a reaction chamber for containing the liquid layer, the chamber comprising a first and a second enclosing element, the first enclosing element comprising a transparent plate placed in the path of the light and contacting the liquid within the chamber, the second enclosing element of the chamber being opposite to the first enclosing element. Positioned in the light path from the light source to the polymerization chamber is a photomask. Collimating optics, e.g. lens assemblies, may be positioned in the light path before or after the photomask. The collimating optics need to be positioned before the transparent plate.

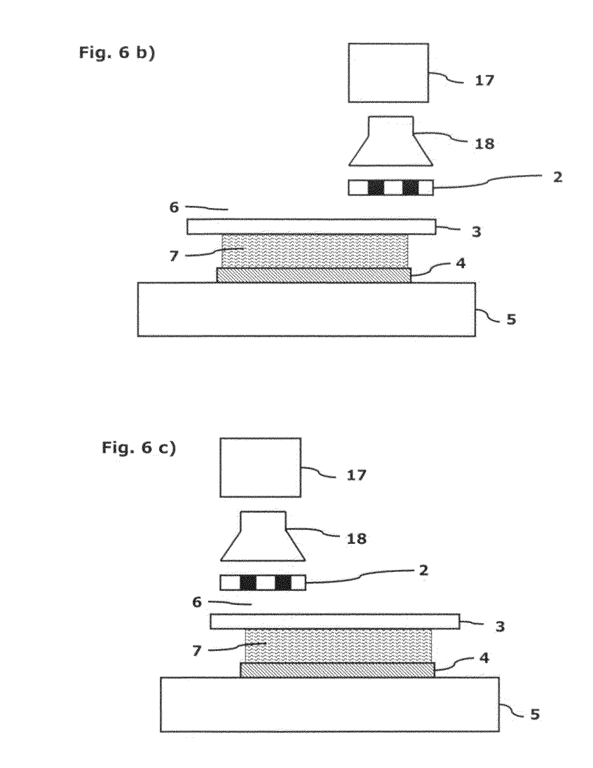

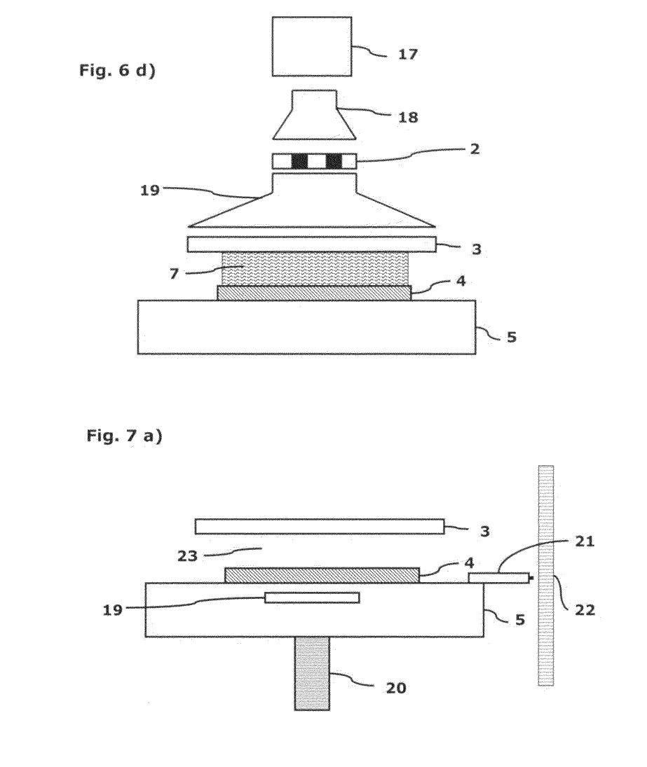

In FIG. 6a-d it is shown how magnification optics may be positioned in the light path before and/or after the photomask to allow for sufficiently large illumination area. In FIG. 6a-c optics that ensure highly collimated light with correct geometry and dimension (18) from the lightsoure (17) is used above the photomask (2) illuminating the whole photomask. The illumination assembly (2, 17,18) can be moved relative to the fabrication area. The actual moving part(s) may be for example the fabrication area or the illumination part(s). The movement may be afforded by two linear stepper motors arranged in such a manner that controlled in plane movement is possible. FIG. 6a shows an example when the illumination assembly is at the center of the fabrication area, FIG. 6b shows the illumination assembly moved to the right side, e.g. via linear stepper motors, and FIG. 6c to the left side of the fabrication area. FIG. 6d. shows an example when the photomask (2) is illuminated to the whole transparent plate (3) by using magnification optics that ensure highly collimated light with correct patterning, geometry and dimensions (19). In preferred embodiments, the light emanating from the optical system is highly collimated, as defined above.

In one embodiment, the first and the second enclosing elements of the chamber are substantially parallel to one another. By substantially parallel, it is meant that the first and second enclosing elements are sufficiently parallel that the thickness variation across the area of the device falls within tolerance limits. In another embodiment, the first and second enclosing elements are not substantially parallel to one another, in which case the polymerized film is not uniform in thickness.

In a preferred embodiment, the separation between the first and second enclosing element is adjustable. Means for adjusting of the separation between the first and second enclosing element can be accomplished by fixing the position of one of the first and second enclosing elements, and attaching the other opposing enclosing element to a positioning device so that one of the elements is movable with respect to the other. For example, the second enclosing element may be attached to a set of microadjustable screws. The substrate is raised using a means of alignment as known in the art, such as micrometer screws (20), until the top of the substrate contacts with the mask, which is the zero thickness layer where the contact is detected using a sensor (23) (a couple of paragraphs down). The distance between the substrate top and the underside of the glass plate is adjusted with micromanipulators as known in the art, for example, microscrews to reach the zero thickness layer, i.e. contact between the two surfaces and the absolute position of the substrate top is recorded using a scale positioned on an unmovable portion of the fabrication machine and an optical reader. The substrate platform is lowered via the microscrews and a liquid polymer precursor is applied on top of the substrate using a pipette.

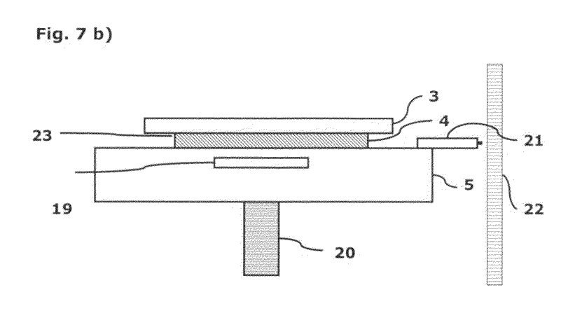

The apparatus also can provide means for measurement of the separation of the first and second enclosing element of the chamber (FIG. 7). Since the separation between the first and second enclosing element of the chamber determines the thickness of the liquid layer inside the reaction chamber, the apparatus allows control of the thickness of the liquid layer. A variety of devices may be used to measure the separation of the first and second enclosing element, including LVDT sensors and readable scales attached to an immobile portion of the machine.

In FIG. 7 a) and 7 b) a scale (22) is read by an optical or magnetic reader (21). For example, the thickness of the liquid layer may be determined as follows: a substrate is placed on a movable bottom plate of the apparatus and a photomask is placed on the top plate of the apparatus. The substrate is raised using a means of alignment as known in the art, such as micrometer screws (20), until the top of the substrate contacts with the mask, which is the zero thickness layer, shown in FIG. 7 b) where the contact is detected using a sensor (19), either situated in the bottom portion or in the plane of the transparent plate, e.g. a sensor detecting the increase in pressure when contact is reached or a sensor detecting a decrease in pressure between the transparent plate and the transparent plate holder when the transparent plate is subjected to a force or an increase in pressure when the transparent plate is forced upwards. Instead of pressure changes, optical means may be used to detect minute movements of the transparent plate, or a sensor that detects an increase in conductivity when the polymer contacts the transparent plate may be used to set the absolute position of the zero thickness layer. The position in the height direction of the substrate is recorded through the use of sensors, readable scales etc. giving an accurate reading of the position of the top of the substrate. The bottom is lowered until there is a desired gap (23) formed between the top of the substrate and the bottom of the transparent plate, thus defining the thickness of the layer that is to be produced.

As to a further discussion of the manner of usage and operation of the present invention, the same should be apparent from the above description. Accordingly, no further discussion relating to the manner of usage and operation will be provided.

With respect to the above description then, it is to be realized that the optimum dimensional relationships for the parts of the invention, to include variations in size, materials, shape, form, function and manner of operation, assembly and use, are deemed readily apparent and obvious to one skilled in the art.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

The features of the present invention will be more clearly understood by reference to the following examples, which are not to be construed as limiting the invention.

### Example 1

A typical liquid polymer precursor is composed of 1% w/w hydroxycyclohexyl phenyl ketone (Irgacure 184, CIBA, Tarrytown, N.Y.) and 0.5% w/w is an arylsulfonium salt (UVI 6976, Dow, Midland, Mich.) as the photoinitiators, in a mixture of 30% (wt/wt) triethyleneglycol diacrylate (Sartomer, Exton, Pa.), 30% hexavinyl aromatic urethane acrylate (EBECRYL 220, Sartomer) and 40% 3,4-Epoxycyclohexylmethyl-3,4-Epoxycyclohexane Carboxylate (UVR 6110, Dow, Midland, Mich.).

Typically, to fabricate a single micro and macro patterned polymeric device layer, a glass substrate is placed on the substrate platform of a fabrication machine and held in position with an underpressure distributed in channels machined on the surface of the substrate platform. A photomask is placed in a frame placed above the fabrication assembly and a transparent glass plate (Borofloat, Schott Scientific, Germany) is placed in a frame positioned between the photomask and the substrate. This glass plate is held in position by underpressure. The distance between the substrate top and the underside of the glass plate is adjusted with micromanipulators as known in the art, for example, microscrews to reach the zero thickness layer, i.e. contact between the two surfaces and the absolute position of the substrate top is recorded using a scale positioned on an unmovable portion of the fabrication machine and an optical reader. The substrate platform is lowered via the microscrews and a liquid polymer precursor is applied on top of the substrate using a pipette. The substrate platform is carefully raised until the liquid polymer precursor touches the underside of the transparent plate. After this point the platform is raised until the desired distance between the substrate top and the underside of the transparent plate is reached. Subsequently, ultraviolet light from a laser light source illuminates the photomask which is placed in the light path and the resulting image is projected onto/into the liquid polymer precursor through the transparent plate. The light source acts on the liquid polymer precursor until the polymer has 20-30% residual double bonds/epoxy groups which normally require an illumination of a few seconds to a few tens of seconds depending on the layer thickness.

After the polymerization, the photomask is raised, the transparent plate is removed via an application of force along one edge, the underpressure is released and the substrate with the polymeric layer is detached. The substrate with the polymeric layer is rinsed in solvent to remove unpolymerized liquid polymer precursor.

### Example 2

Multilayer devices are fabricated in the same manner as above, with a first layer following the process of Example 1. Layer two utilizes the first layer as a substrate and alignment between features on the first layer and the photomask used for the second layer is ensured using optical or other means and microscrews to move the mask and the fabrication area relative to one another.

### Example 3

Multilayer devices with undercuts are fabricated in the same manner as Example 2 until the point where the undercut is reached. The layer that forms the top portion of the undercut is fabricated separately using the transparent plate as the substrate. Turning the transparent plate upside down and securing it in the fabrication machine affords a sandwich like structure where the top is positioned on the contact side of the transparent plate and the bottom portion of the device is positioned on the substrate. A thin layer of liquid polymer precursor consisting solely of TEGDA is applied between the two polymeric portions, a light pressure, where the compressive force is recorded via a sensor, is applied to ensure proper contact between the plates, and the assembly is illuminated for 5-30 seconds to ensure that active species on both polymeric portions polymerize the TEGDA where the portions are in contact/very close proximity. The device is finished similarly to Example 1.

What is claimed is:

1. A method for producing a plurality of geometrically structured polymeric layers comprising:
a) placing a substrate on top of a base, the substrate having a liquid polymer precursor contained between the top of the substrate and the underside of an essentially transparent plate that is placed parallel to the substrate; b) placing a photomask above and parallel to the transparent plate; c) placing a light source above the photomask so that highly collimated light impinges on the photomask at an angle normal to the photomask plane, and upon irradiation, a photomask determined pattern is projected onto the liquid polymer precursor and patterned polymer structures are formed.

2. The method of claim 1, wherein the highly collimated light simultaneously covers at least a substantial portion of the photomask.

3. The method of claim 1, further comprising removing any unpolymerized region or regions of the liquid.

4. The method of claim 2 where the highly collimated light is produced by a laser light source and passed through magnification optics before impinging on the photomask.

5. The method of claim 2 wherein the substrate comprises a previously polymerized layer or previously polymerized layers on top of a solid base for the fabrication of multilayer structures.

6. The method of claim 2 wherein the liquid polymer precursor contains a photoinitiator.

7. The method in claim 2 wherein the liquid polymer precursor contains reactive chemical groups that lack significant reactivity in the polymer forming process.

8. The method of claim 2 wherein the essentially transparent plate has a surface on the side facing the photoreactive polymer precursor that is modified by chemicals.

9. The method of claim 8 wherein the chemicals are essentially inert under normal photopolymerization conditions and form a release layer between the formed polymer and the essentially transparent plate.

10. The method of claim 8 wherein where the chemicals are reactive chemicals that impart or transfer chemical reactivity to surfaces and liquids that are to be covalently bound in later process stages.

11. A method for producing undercuts comprising a) providing a previously polymerized layer attached to the essentially transparent plate on the side facing the substrate; b) providing means to align said substrate to the previously polymerized layer; c) contacting the surfaces of the substrate and the previously polymerized layer; d) binding the surfaces covalently via light initiated chemical reactions; and e) detaching the essentially transparent plate from the attached previously polymerized layer.

12. The method of claim 11 where the substrate comprises a substrate base and one or more previously polymerized layers.

13. An apparatus for producing a plurality of geometrically structured polymeric layers, the apparatus comprising: a) a reaction chamber comprising a moveable base and an essentially transparent plate placed in parallel to the moveable base wherein the surfaces of the reaction chamber and transparent plate that are opposite each another serve to contain a liquid polymer precursor; b) a photomask placed above at a finite distance and in parallel to the reaction chamber and the transparent plate; and c) a light source providing highly collimated light.

14. The apparatus of claim 13 wherein the highly collimated light from the light source projects an image onto the essentially transparent plate at an angle essentially normal to the plane of the plate.

15. The apparatus of claim 13 further comprising means for alignment between the photomask and substrate features.

16. The apparatus of claim 13 further comprising micromanipulators for alignment and layer thickness control through adjustment of the distance between the enclosing surfaces of the reaction chamber.

17. The apparatus of claim 13 wherein the reaction chamber is movable with respect to the photomask and light source.

18. The apparatus of claim 17 further comprising linear stepper motors for high precision in plane movement.
